(19) United States
(12) Patent Application Publication
(10) Pub. No.: US 2002/0027681 A1
(43) Pub. Date: Mar. 7, 2002

(54) Gate stack process for high reliability dual oxide CMOS devices and circuits

(75) Inventors: John M. Aitken, South Burlington, VT (US); Alvin W. Strong, Essex Junction, VT (US); Ernest Y. Wu, Essex Junction, VT (US)

Correspondence Address: I B M CORP., 1580 RTE. 52, BUILDING 300 2/482, HOPEWELL JUNCTION, NY, 12533, US

(73) Assignee: International Business Machines Corportion, Armonk, NY

(21) Appl. No.: 09/924,010

(22) Filed: Aug. 7, 2001

Related U.S. Application Data
(63) Continuation of application No. 09/464,509, filed on Dec. 15, 1999.

(51) Int. Cl. H01L 21/3205

(52) U.S. Cl. 359/109; 257/84; 438/585

(57) ABSTRACT

1. A method of forming multiple oxide thicknesses on a base, according to the following steps:

a) forming a layer of a first oxide on a base having an area, a, a first thickness and a first surface, the base having a top surface;

b) depositing a first layer of polysilicon film having a second thickness on the first oxide layer, the first layer of polysilicon film having a second surface;

c) removing a region of the first oxide and the first polysilicon, such that the base is exposed, and wherein a second thickness of oxide is desired over at least a portion of the region;

d) forming a layer of a second oxide, having a third surface and a third thickness, on at least substantially all of the portion of the region where a second oxide thickness is desired, the third thickness not equal to the first thickness;

e) depositing a second layer of polysilicon film having a fourth surface and a fourth thickness on at least the layer of second oxide such that the fourth thickness plus the third thickness is at least greater than the first thickness.

### FIELD OF THE INVENTION

This invention is directed to the manufacture of semiconductor devices and more particularly to the fabrication of transistors with variable thickness gate oxides.

### BACKGROUND OF THE INVENTION

The use of Metal-Oxide-Silicon (MOS) transistors is widespread in the semiconductor industry. Each generation of semiconductor chip achieves a wider variety of functions at a greater density than previous ones. The proliferation of chips and power supplies can lead to the problem of interfacing chips of one type with those of another. For example, transistors on one chip designed to operate at a specific power supply voltage have to communicate with transistors from other chips operating at different voltages. Thus, the output voltages from the first chip must be compatible with the input circuits of the second, necessitating two separate transistor designs on the second chip. For example one chip with 5 volt outputs must interface with the input circuits of a chip whose supply voltage is 3 volts. In this case the input transistors on the 3 volt chip must operate reliably with the higher 5 volt input. This requires a customized design for the chip when it is being fabricated to allow a higher voltage to be applied without causing a failure of the transistor. One of the limiting factors of the maximum applied voltage is the gate oxide thickness. The maximum voltage formula is Vₘₐₓ=k₁* Tₒₓ where k₁ is a constant dependent on the material selected and Tₒₓ is the oxide thickness. As can be seen from the formula, Vₘₐₓ is linearly proportional to the oxide thickness. Therefore, ideally a thicker oxide is required in the input devices which will see the higher voltage from the other chip. Increasing the oxide thickness allows the circuit designer to raise the voltage on the device without causing premature or unpredictable dielectric failure. The other devices on the chip operating at 3 volts, must have a thinner oxide than the input devices otherwise they will not perform optimally. In another case two devices on the same chip may perform different functions that depend on the electric field imposed across them by some common voltage. This also requires that two separate gate oxide thicknesses are present on the same chip.

There are a number of known methods which result in transistors with variable gate oxide thicknesses, however each has limitations. In one method a layer of oxide is formed and then a photoresist layer is deposited and the oxide itself etched. The method requires that extensive cleaning be done to remove the contamination introduced by the photoresist. The quality of the oxide can be degraded by these processing steps. Other methods dope sections of the underlying silicon with Nitrogen to retard the growth of oxide in that region. Additional implantation steps are required with this method and a silicon nitride layer is formed which is usually not desirable in an active region and can negatively impact reliability. Another method, currently in use, is shown in FIG. 1. The method involves using a set of sequential similar processing steps to deposit a first oxide of a given thickness on a device's previously defined active area, (1) then deposit a first polysilicon layer (5). An etch is then done which would define the gate stack for that transistor and a first layer of an insulator is deposited (2). The process is then complete and is performed again. A different device's active area would then be identified (10). An etch would be performed to expose the active area. A second oxide of a different thickness would be deposited (3), and a second layer of polysilicon deposited (6). The gate stack would then be defined by an etch and a second layer of an insulator deposited (4). As can be seen from the figure the topography may not be regular presenting a problem in subsequent processing steps. Additionally, there is the problem of residual first polysilicon outside of the active area of the second transistor. Thus there remains a need for a method of forming different gate thickness prior to the etching of any of the transistors. There also remains a need for a method of forming different gate thickness which does not introduce further processing complexity and unwanted irregular topography.

### SUMMARY OF THE INVENTION

It is therefore an object of the present invention to provide a method for producing devices with variable oxide thickness where the performance parameters are not degraded. It is also an object of the present invention to a method of producing multiple gate oxide thicknesses for metal-oxide-silicon transistors with smooth subsequent topography. In accordance with these and other objects, we invent a method of forming multiple oxide thicknesses on a base, comprising the following steps:

a) forming a layer of a first oxide on a base having an area, a, a first thickness and a first surface, the base having a top surface;

b) depositing a first layer of polysilicon film having a second thickness on the first oxide layer, the first layer of polysilicon film having a second surface;

c) removing a region of the first oxide and the first polysilicon, such that the base is exposed, and wherein a second thickness of oxide is desired over at least a portion of the region;

d) forming a layer of a second oxide, having a third surface and a third thickness, on at least substantially all of the portion of the region where a second oxide thickness is desired, the third thickness not equal to the first thickness;

e) depositing a second layer of polysilicon film having a fourth surface and a fourth thickness on at least the layer of second oxide such that the fourth thickness plus the third thickness is at least greater than the first thickness.

### BRIEF DESCRIPTION OF THE DRAWINGS

These and other features, aspects, and advantages will be more readily apparent and better understood from the following detailed description of the invention, in which:

FIG. 1 is a cross sectional view of previous work showing topography of double polysilicon dual gate oxide process.

FIGS. 2a-2g show cross sectional views of the method and structure of the instant invention.

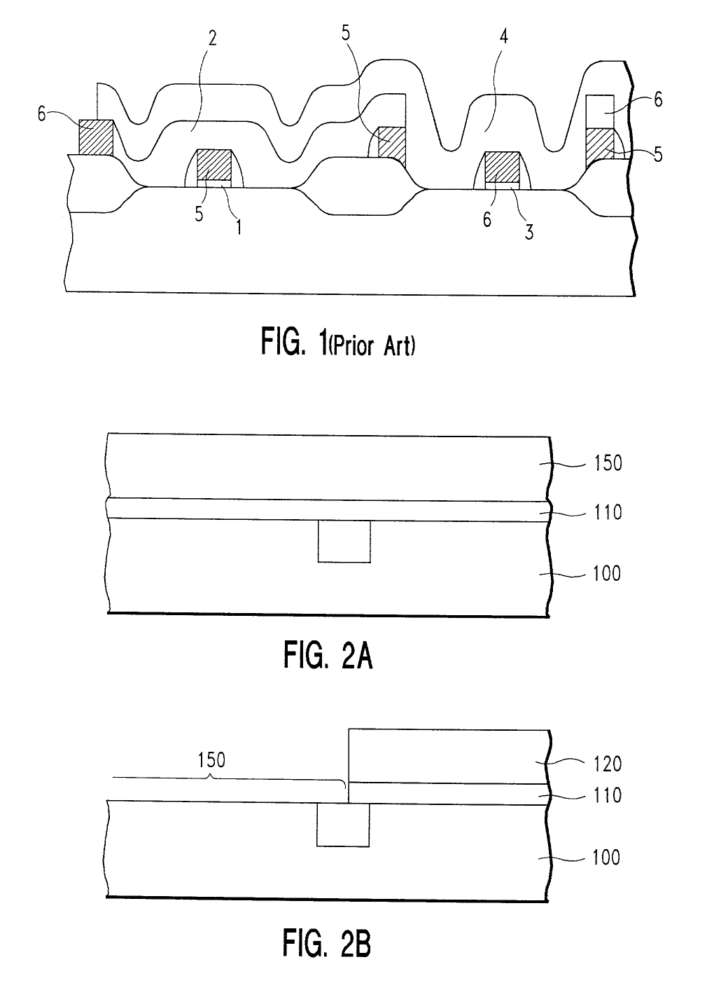

### DETAILED EMBODIMENT

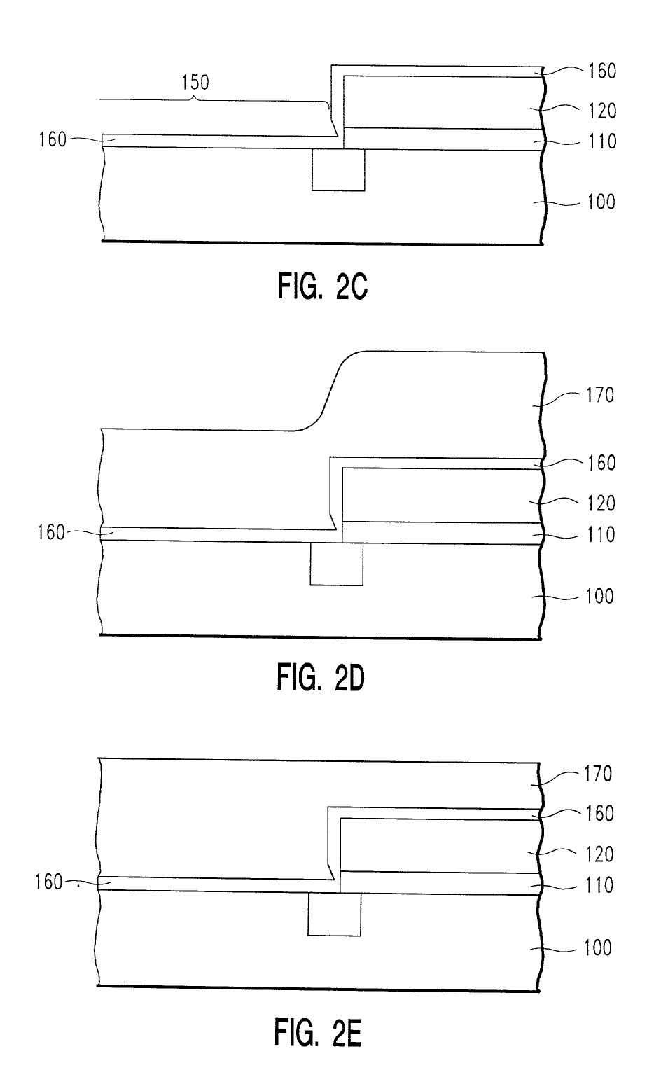

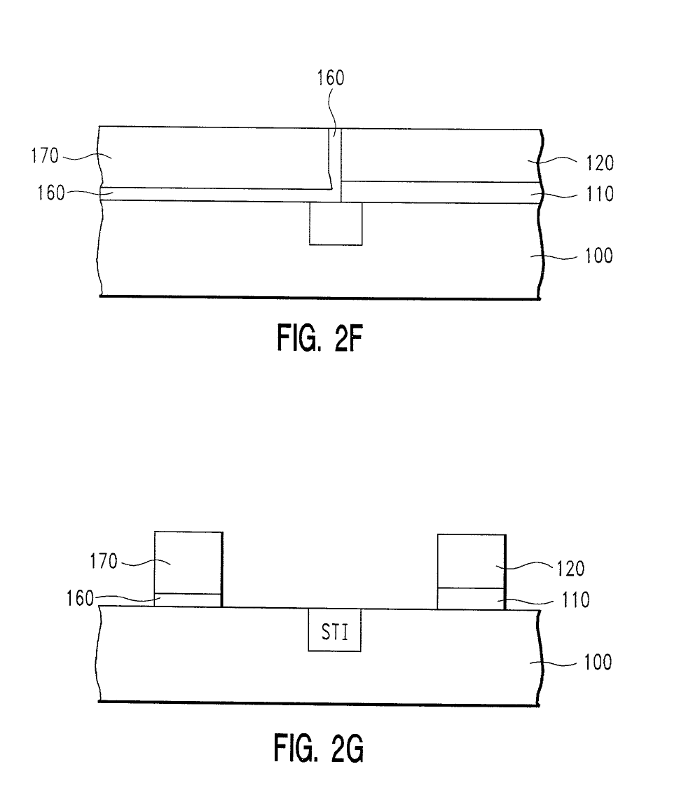

The method of instant invention creates oxides of varied thickness having a smooth topography and the process is extendable such that any number of thicknesses can be achieved on a given chip. The method is shown in FIGS. 2a-2g. The figures are meant to be illustrative only and are not drawn to scale. The circuit designer or other person, must define the area on a chip where gate oxides of multiple thickness are sought, that user defined area will hereafter be referred to as area, A. According to the method of the instant invention, first a layer of an arbitrary thickness of a first oxide, 110, is deposited on a silicon substrate or other base, 100, as shown in FIG. 2a. The first oxide should be formed over substantially all of area A. The thickness of the first oxide should be the thickness sought for at least one of the transistor gate oxides hereafter the first gate oxide. Next, a first layer of polysilicon, 120, also having an arbitrary thickness, is deposited on the first oxide as shown in FIG. 2a. The layer of polysilicon should be deposited over substantially all of area A. Following the deposition of the first polysilicon layer a region, 150, of the coated silicon substrate will be etched as shown in FIG. 2b. The region can be defined as the part of the area A where at least one transistor with a gate oxide thickness which is different from the thickness of the first gate oxide, 110, is desirable, hereafter called the region. The region would have boundaries, have a surface area and the region would most preferably be a subset of the area. The region creating etch would remove substantially all of the first oxide and the first polysilicon layers formed in the previous two steps. Next, a second oxide layer, 160, is formed, preferably over substantially all of the area A, as shown in FIG. 2c, but at least over substantially all of the region. As shown in FIG. 2c the second oxide, 160, can be deposited on the first polysilicon, 120. The final layer deposited is a second polysilicon layer, 170, as shown in FIG. 2d. Preferably, the thickness of the second polysilicon layer plus the second oxide layer should be at least be equal to, and more preferably greater than, the thickness of the first polysilicon layer plus the first silicon layer.

Once the four layers have been deposited and/or formed the layered substrate will probably need treatment. In the final layered substrate the topmost layer should preferably comprise the first polysilicon. Usually, at least the topmost layer of at least the region and probably the area A will need to be treated since the second oxide and the second polysilicon have been deposited after the first oxide and the first polysilicon. There are many methods that may be used to treat the region and area A. Preferably, the treatment would comprise two steps. First, the topmost which preferably comprises the second polysilicon would be planarized. Second, the planarized second polysilicon layer would be treated such that the final topmost surface would also be planar, but the treatment would continue until at least the second oxide layer formed on the first polysilicon is substantially completely removed as shown in FIG. 2F. After the layered structure is formed, it is possible to etch user defined features.

In a more preferred embodiment the base, silicon substrate, while planar, would have features, the features having a measurable surface area. For example, the features could comprise shallow trench isolation (STI). The presence of the STI would facilitate the treatment of the layered structure in that it would make the planarization process easier. The processing steps of the method of the instant invention would be substantially the same. In an even more preferred embodiment, at least a portion of the surface area of the silicon substrate exposed after the deposition of the first polysilicon layer (the region) would comprise the surface area of at least one feature. In a most preferred embodiment, less then 100% of the surface area of the feature would be exposed by the etch which creates the region. It should also be noted that the first or second polysilicon can be doped at any point in the process if the user defined final structure makes doping desirable.

An example of the processing flow for the method is given below. First, a layer of oxide is deposited. Preferably, the oxide would be grown and be at least about 5 nm in thickness. A layer of polysilicon is deposited on a layer of silicon substrate. Preferably, the polysilicon would be chemically vapor deposited and would be about 0.25 microns thick. Also preferably, the layer of silicon substrate would have shallow trench isolation portions. Next the active area for the second transistor having a different gate thickness would be defined using standard photolithographic and etching techniques. Preferably reactive ion etching would be used. Next, a second oxide film would be deposited on at least the active area of the second transistor. Preferably, the second oxide film thickness would be less than the thickness of the first oxide film. Preferably, the thickness of the second oxide film would be at least about 2 and at most about 5 nm. More preferably, the surface would be cleaned, using standard methods prior to growing the second oxide. Next, a second polysilicon layer would be deposited. Preferably, the thickness of the second polysilicon layer would be equal to the thickness of the first polysilicon layer plus the difference between the first oxide thickness and the second oxide thickness. At this point processing can proceed according to user defined processing to create transistor with different gate oxide thickness.

Preferably further processing includes a first chemical mechanical polishing (CMP) to planarize the second polysilicon layer then a second CMP using the first oxide as an etch stop or marker. The transistors with different gate thickness would then be defined using standard photolithographic and etching process.

While the invention has been described in terms of specific embodiments, it is evident in view of the foregoing description that numerous alternatives, modifications and variations will be apparent to those skilled in the art. Thus, the invention is intended to encompass all such alternatives, modifications and variations which fall within the scope and spirit of the invention and the appended claims.

What is claimed:

1. A method of forming multiple oxide thicknesses on a base, comprising the following steps:
a) forming a layer of a first oxide on a base having an area, a, a first thickness and a first surface, the base having a top surface;
b) depositing a first layer of polysilicon film having a second thickness on the first oxide layer, the first layer of polysilicon film having a second surface;
c) removing a region of the first oxide and the first polysilicon, such that the base is exposed, and wherein a second thickness of oxide is desired over at least a portion of the region;
d) forming a layer of a second oxide, having a third surface and a third thickness, on at least substantially all of the portion of the region where a second oxide thickness is desired, the third thickness not equal to the first thickness;
e) depositing a second layer of polysilicon film having a fourth surface and a fourth thickness on at least the layer of second oxide such that the fourth thickness plus the third thickness is at least greater than the first thickness.

2. The method according to claim 1 wherein the second oxide layer is formed over substantially all of the area, a, and the region and the second polysilicon layer is deposited over substantially all of the second oxide layer.

3. The method according to claim 2 further comprising the step of treating the fourth surface such that the second surface is the exposed.

4. The method according to claim 3 wherein the treating comprises planarizing the second polysilicon layer such that the third surface is exposed.

5. The method according to claim 4 wherein the treating further comprises planarizing the second oxide such that the second surface is exposed.

6. The method according to claim 1 wherein the base comprises at least one feature having a topmost surface, the topmost surface area, b.

7. The method of claim 6 where at least one feature is shallow trench isolation and the topmost surface of the shallow trench isolation is substantially planar to the top surface of the base.

8. The method according to claim 7 wherein the base exposed in step c) includes at least some of the topmost surface area, b, of the feature.

9. The method according to claim 8 wherein the base exposed in step c) includes less than 100% of the topmost surface area, b, of the feature.

10. The method according to claim 8 wherein the base exposed in step c) includes about 50% of the topmost surface area, b, of the feature.

11. The method according to claim 1 wherein the third thickness plus the fourth thickness is at least equal to the second thickness plus the first thickness.
